(19) United States
(12) Patent Application Publication
(10) Pub. No.: US 2024/0223080 A1
(43) Pub. Date: Jul. 4, 2024

(54) NEGATIVE VOLTAGE GENERATOR WITH A CHARGE PUMP CIRCUIT AND OPERATING METHOD THEREOF

(71) Applicant: SAMSUNG ELECTRO-MECHANICS CO., LTD., Suwon-si (KR)

(72) Inventors: Shinhaeng HEO, Suwon-si (KR); Byeonghak JO, Suwon-si (KR); Wonsun HWANG, Suwon-si (KR); Dongil KANG, Suwon-si (KR); Hyunjin YOO, Suwon-si (KR)

(73) Assignee: SAMSUNG ELECTRO-MECHANICS CO., LTD., Suwon-si (KR)

(21) Appl. No.: 18/318,946

(22) Filed: May 17, 2023

(30) Foreign Application Priority Data
Dec. 30, 2022 (KR) 10-2022-0190559

(51) Int. Cl. H02M 3/07; H02M 1/00; H02M 1/088

(52) U.S. Cl. CPC H02M 3/071; H02M 1/0025; H02M 1/088

(57) ABSTRACT

A charge pump circuit includes a pump capacitor, a first transistor group configured to charge the pump capacitor based on a first clock signal having a first frequency, and a second transistor group configured to charge the pump capacitor based on a second clock signal having a second frequency different from the first frequency. A size of the second transistor group is different from a size of the first transistor group.

### CROSS-REFERENCE TO RELATED APPLICATION

This application claims the benefit under 35 USC § 119(a) of Korean Patent Application No. 10-2022-0190559, filed on Dec. 30, 2022, in the Korean Intellectual Property Office, the entire disclosure of which is incorporated herein by reference for all purposes.

### BACKGROUND

### 1. Field

The present disclosure relates to a charge pump circuit and an operating method thereof.

### 2. Description of the Related Art

A radio frequency (RF) switch may be used in a communication module's transmitting and receiving end to pass or block an RF signal. In addition, the RF switch may serve to select a frequency band.

The RF switch may be implemented as a switch transistor performing a switch function. The switch transistor may perform an on/off operation by a control voltage input to a control terminal. The switch transistor may be turned on when the control voltage is positive (+), and the switch transistor may be turned off when the control voltage is negative (−). The switch transistor may be turned off more reliably when the control voltage is negative (−). Here, a charge pump circuit generating the negative (−) voltage may be used for the control voltage to have the negative (−) voltage.

A clock signal may operate the charge pump circuit, and the clock signal may have a predetermined frequency. The frequency of the clock signal may cause a spur in the charge pump circuit or affect the charge pump circuit's negative (−) output voltage.

The above information disclosed in this Background section is only for enhancement of understanding of the background of the present disclosure, and therefore it may contain information that does not form the prior art that is already known in this country to a person of ordinary skill in the art.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a charge pump circuit includes a pump capacitor, a first transistor group configured to charge the pump capacitor based on a first clock signal having a first frequency, and a second transistor group configured to charge the pump capacitor based on a second clock signal having a second frequency different from the first frequency. A size of the second transistor group is different from a size of the first transistor group.

The second frequency may be higher than the first frequency, and the size of the second transistor group may be larger than the size of the first transistor group.

The first transistor group may be operated in a first mode, and the second transistor group may be operated in a second mode.

The second mode may be a start-up mode of the charge pump circuit, and the first mode may be different than the start-up mode.

The second frequency may be higher than the first frequency, and the size of the second transistor group may be larger than the size of the first transistor group.

In the first mode, a communication module including the charge pump circuit may be in a reception mode, and in the second mode, the communication module may be in a transmission mode.

The second frequency may be higher than the first frequency, and the size of the second transistor group may be larger than the size of the first transistor group.

The circuit may further include a third transistor group configured to charge the pump capacitor based on a third clock signal having a third frequency different from the second frequency. The size of the first transistor group, the size of the second transistor group, and a size of the third transistor group may be different from one another.

The second frequency may be higher than the first frequency, and the third frequency may be higher than the second frequency. The size of the second transistor group may be larger than the size of the first transistor group, and the size of the third transistor group may be larger than the size of the second transistor group.

The first transistor group may be operated in a first mode, the second transistor group may be operated in a second mode, and the third transistor group may be operated in a third mode.

In the first mode, a communication module including the charge pump circuit may be in a reception mode. In the second mode, the communication module may be in a transmission mode, and in the third mode, the charge pump circuit may be in a start-up mode.

A negative voltage generator may include the circuit described above, and an oscillator configured to generate the first clock and the second clock to drive the first transistor group and the second transistor group, respectively.

In another one or more general aspects, an operating method of a charge pump circuit, includes generating, in a first mode, a negative voltage using a first transistor group based on a first clock signal; and generating, in a second mode, the negative voltage using a second transistor group based on a second clock signal. A frequency of the second clock signal is different from a frequency of the first clock signal, and a size of the second transistor group is different from a size of the first transistor group.

The frequency of the second clock signal may be higher than the frequency of the first clock signal, and the size of the second transistor group may be larger than the size of the first transistor group.

The second mode may be a start-up mode of the charge pump circuit, and the first mode may be a different mode than the start-up mode.

In the first mode, a communication module including the charge pump circuit may be in a reception mode, and in the second mode, the communication module may be in a transmission mode.

The method may further include generating, in a third mode, the negative voltage using a third transistor group based on a third clock signal. A frequency of the third clock signal may be different from the frequency of the second clock signal, and a size of the third transistor group may be different from the size of the second transistor group.

The second frequency may be higher than the first frequency, and the third frequency may be higher than the second frequency. The size of the second transistor group may be larger than the size of the first transistor, and the size of the third transistor may be larger than the size of the second transistor group. In the first mode, a communication module including the charge pump circuit may be in a reception mode, in the second mode, the communication module may be in a transmission mode, and in the third mode, the charge pump circuit may be in a start-up mode.

In another one or more general aspects, a negative voltage generator include a charge pump circuit including a pump capacitor and a plurality of transistor groups having different sizes; and an oscillator configured to generate a plurality of clock signals having different frequencies to drive the plurality of transistor groups, respectively. Each of the plurality of transistor groups is configured to charge the pump capacitor based on a corresponding clock signal of the plurality of clock signals.

A second frequency of the different frequencies may be higher than a first frequency of the different frequencies, a size of a second transistor group of the plurality of transistor groups may be larger than a size of a first transistor group of the plurality of transistor groups, and the second transistor group may be operated in a start-up mode, and the first transistor group may be operated in a different than the start-up mode.

Other features and aspects will be apparent from the following detailed description, the drawings, and the claims.

### BRIEF DESCRIPTION OF THE DRAWINGS

FIG. 1 is a block diagram showing a negative voltage generator according to one or more embodiments.

FIG. 2 shows an example a charge pump circuit.

FIG. 3A shows an operational state of the charge pump circuit in a first operation period.

FIG. 3B is a view showing an operational state of the charge pump circuit in a second operation period.

FIG. 4 shows a relationship between a frequency of a clock signal and a size of a transistor.

FIG. 5 is a circuit diagram showing a charge pump circuit in one or more embodiments.

FIG. 6 is a circuit diagram showing a charge pump circuit in still another one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

Throughout this specification, a radio frequency (RF) signal may have formats based on protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access + (HSPA+), high speed downlink packet access + (HSDPA+), high speed uplink packet access + (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols, and is not limited thereto.

In addition, when a part “includes” any component, it may indicate the inclusion of other components rather than the exclusion of other components unless explicitly described to the contrary.

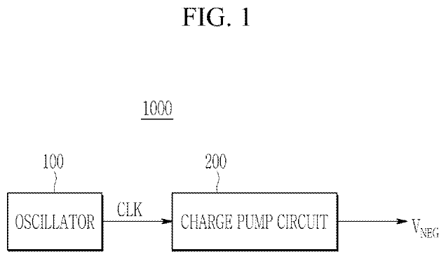

FIG. 1 is a block diagram showing a negative voltage generator 1000 according to one or more embodiments.

As shown in FIG. 1, according to one or more embodiments, the negative voltage generator 1000 may include an oscillator 100 and a charge pump circuit 200.

The oscillator 100 may generate a clock signal CLK desired to drive the charge pump circuit 200. Here, the clock signal CLK may have a predetermined frequency. A method of generating the clock signal by the oscillator 100 may be known to those skilled in the art, and the description thus omits a detailed description thereof.

The charge pump circuit 200 may be driven (or operated) by the clock signal CLK output from the oscillator 100, and generate and output a negative voltage V_{NEG}. For example, the negative voltage V_{NEG} generated by the charge pump circuit 200 may be used to turn on or off a switch transistor.

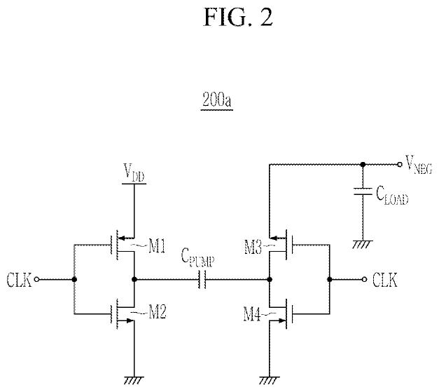

FIG. 2 is a view showing an example of a charge pump circuit.

As shown in FIG. 2, a charge pump circuit (e.g., charge pump circuit 200a) may include a transistor M1, a transistor M2, a transistor M3, a transistor M4, a pump capacitor C_{PUMP}, and a load capacitor C_{LOAD}.

In FIG. 2, the transistors M1 to M4 may be various types of transistors, each functioning as a switch, such as a field-effect transistor (FET) or a bipolar transistor. The transistors M1 to M4 may be substituted by other transistors even though the following description assumes that the transistors are the FETs for convenience. In addition, the transistors M1 and M4 may be n-type transistors, and the transistors M2 and M3 may be p-type transistors even though FIG. 2 shows the transistors M1 and M4 as the p-type transistors, and the transistors M2 and M3 as the n-type transistors. Meanwhile, a gate of the transistor may serve as a control terminal and be called the “control terminal.”

A source of the transistor may be one terminal of the transistor and be called a “first terminal” or a “second terminal.”

A drain of the transistor may also be one terminal of the transistor and be called the “first terminal” or the “second terminal.”

A source of the transistor M1 may be connected to a power supply voltage V_{DD}, and a drain of the transistor M1 and a drain of the transistor M2 may be connected to each other. A source of the transistor M2 may be connected to the ground. In addition, the clock signal CLK may be input to a gate of the transistor M1 and a gate of the transistor M2.

A source of the transistor M3 may be connected to one end of a load capacitor C_{LOAD}, and the negative voltage V_{NEG} may be output from the source of the transistor M3. A drain of the transistor M3 and a drain of the transistor M4 may be connected to each other, and a source of the transistor M4 may be connected to the ground. In addition, the clock signal CLK may be input to a gate of the transistor M1 and a gate of the transistor M4. The clock signal CLK applied to the gate of the transistor M3 and the gate of the transistor M4 and the clock signal CLK applied to the gate of the transistor M1 and the gate of the transistor M2 may be the same clock signal.

One end of the pump capacitor C_{PUMP} may be connected to the drain of the transistor M1 and the drain of the transistor M2. In addition, the other end of the pump capacitor C_{PUMP} may be connected to the drain of the transistor M3 and the drain of the transistor M4.

In addition, the load capacitor C_{LOAD} may be connected between the source of the transistor M3 and the ground. The load capacitor C_{LOAD} may stabilize the negative voltage V_{NEG} output from the charge pump circuit 200a.

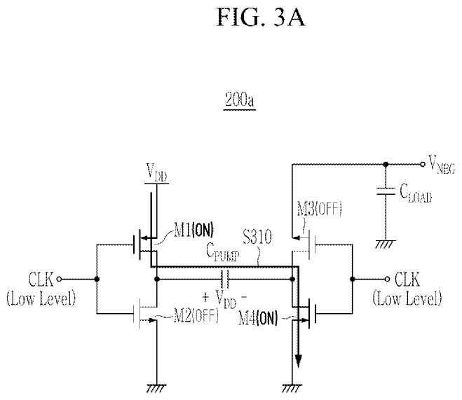

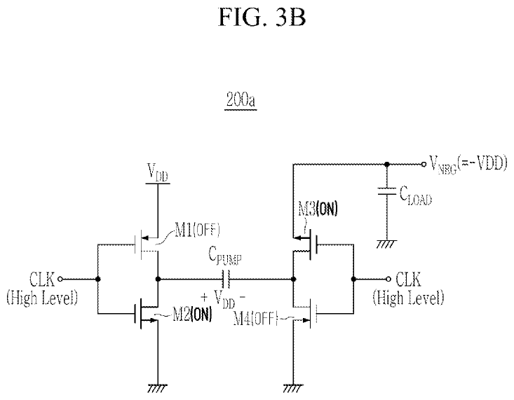

The charge pump circuit 200a may have two operation periods. An operation of charging the pump capacitor C_{PUMP} may be performed in a first operation period, and an operation of outputting the negative voltage V_{NEG} may be performed in a second operation period. This configuration is described in more detail in FIGS. 3A and 3B below.

FIG. 3A shows the operational state of the charge pump circuit 200a in the first operation period.

In the first operation period, the clock signal CLK may be low. By the low-level clock signal CLK, the transistors M1 and M4 may be turned on, and the transistors M2 and M3 may be turned off. Accordingly, a current channel S310 may be formed through the power supply voltage V_{DD}, the transistor M1, the pump capacitor C_{PUMP}, the transistor M4, and the ground. Through this current channel S310, the pump capacitor C_{PUMP} may be charged with the power supply voltage V_{DD}.

FIG. 3B shows the operational state of the charge pump circuit 200a in a second operation period.

In the second operation period, the clock signal CLK may be high. By the high-level clock signal CLK, the transistors M2 and M3 may be turned on, and the transistors M1 and M4 may be turned off. The pump capacitor C_{PUMP} may maintain the power supply voltage V_{DD} charged in the first operation period, and one end of the pump capacitor C_{PUMP} may be connected to the ground through the transistor M2. Accordingly, a voltage at the other end of the pump capacitor C_{PUMP} becomes −V_{DD}, and the pump capacitor C_{PUMP} may output the negative voltage V N_{EG}, which is −V_{DD}. That is, the negative voltage V N_{EG} having −V_{DD} may be output through the load capacitor C_{LOAD}.

The first and second operation periods may be repeated a predetermined number of times by the clock signal CLK. The charge pump circuit 200a may substantially output the negative voltage V_{NEG} by this repetitive operation.

Meanwhile, in the charge pump circuit 200a, the sizes of the transistors M1 to M4 and the frequency of the clock signal CLK may be set to have an appropriate relationship, and the description describes this relationship.

In the first operation period, as shown in FIG. 3A, the pump capacitor C_{PUMP} may be charged with an RC time constant rather than being immediately charged. That is, the voltage V_{CPUMP} charged across the pump capacitor C_{PUMP} may have a relationship of Equation 1 below.

$${V}_{CPUMP} = {V}_{DD} ( 1 - \frac{1}{{e}^{\frac{t}{RC}}} ) \qquad ( Equation 1 )$$

In Equation 1, C represents the capacitance value of the pump capacitor C_{PUMP}, and R represents a resistance value present on the current channel S310 in FIG. 3A. For example, R may be the sum of the turn-on resistance of the transistor M1 and the turn-on resistance of the transistor M4. Referring to Equation 1 above, the voltage V_{CPUMP} depends on an RC value, which is a time constant. Here, the capacitance value of the pump capacitor C_{PUMP} has a preset fixed value, and the voltage V_{CPUMP} may thus be determined by R.

In general, a turn-on resistance R_{ON} of a transistor may be expressed by Equation 2 below.

$${R}_{ON} = \frac{1}{{μ}_{n} {C}_{ox} \frac{W}{L} ( {V}_{GS} - {V}_{TH} )} \qquad ( Equation 2 )$$

In Equation 2, represents electron mobility in the channel, and represents a capacitance per unit area for a capacitor formed between the gate and the channel. W represents the width of the channel, and L represents the length of the channel. V_{GS} represents a voltage between the gate and source, and V_{TH} represents a threshold voltage.

W/L in Equation 2 may be expressed as the “size of the transistor.”

A larger size of the transistor may indicate a larger W/L value, and a smaller size of the transistor may indicate a smaller W/L value. In Equation 2, R_{ON} is smaller when the W/L value is larger. Accordingly, the larger size of the transistor may indicate a smaller turn-on resistance value, and the smaller size of the transistor may indicate a larger turn-on resistance value.

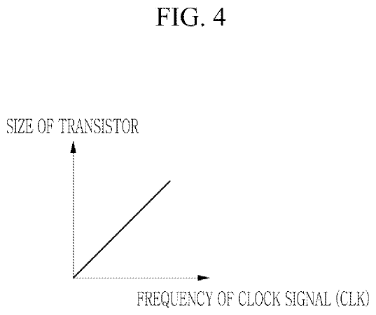

The frequency of the clock signal C_{LK} needs to be properly set for the pump capacitor C_{PUMP} to be sufficiently charged up to the power supply voltage V_{DD}. The turn-on resistance value may be larger when the size of the transistor is smaller, and an RC time constant value may thus be larger. In this case, the pump capacitor C_{PUMP} may be sufficiently charged up to the power supply voltage V_{DD} by setting the frequency of the clock signal CLK low. In addition, the RC time constant value may be smaller when the size of the transistor is larger, and the turn-on resistance value may thus be smaller. In this case, the pump capacitor C_{PUMP} may be sufficiently charged up to the power supply voltage V_{DD} by setting the frequency of the clock signal CLK high. That is, the frequency of the clock signal CLK and the size of the transistor may satisfy a relationship shown in FIG. 4.

FIG. 4 shows the relationship between the frequency of the clock signal CLK and the size of the transistor.

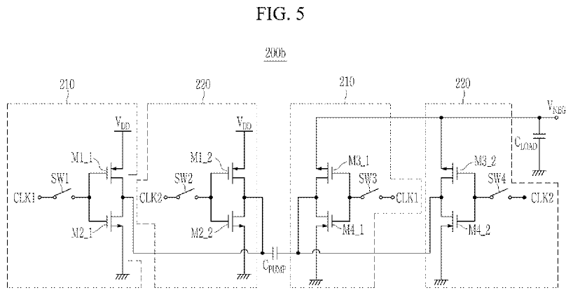

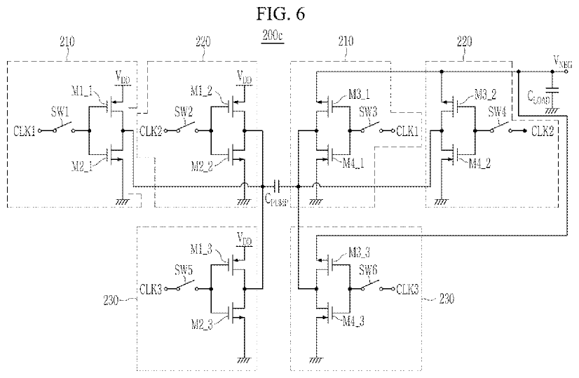

In the charge pump circuit, the frequency of the clock signal CLK may be set to a different value as needed rather than being set to the same value. The size of the transistor having the relationship shown in FIG. 4 may be designed when the frequency of the clock signal CLK is set to a different value. For example, when the frequency of the clock signal CLK is high, the charge pump circuit may be designed more stably by setting the size of the transistor to be large. The description describes the design of this charge pump circuit in detail with reference to FIGS. 5 and 6 below.

FIG. 5 is a circuit diagram showing a charge pump circuit in one or more embodiments.

As shown in FIG. 5, the charge pump circuit 200b in one or more embodiments may include a first transistor group 210 operated in a first mode, a second transistor group 220 operated in a second mode, a pump capacitor C_{PUMP}, and a load capacitor C_{LOAD}.

The first transistor group 210 may be operated in the first mode and driven (or operated) by a clock signal CLK1. The first transistor group 210 may include a transistor M1_1, a transistor M2_1, a transistor M3_1, and a transistor M4_1. In terms of the pump capacitor C_{PUMP} and the load capacitor C_{LOAD}, a connection relationship of the transistors M1_1 to M4_1 may be similar to that of the transistors M1 to M4 in FIG. 2.

A source of the transistor M1_1 may be connected to a power supply voltage V_{DD}, and a drain of the transistor M1_1 and a drain of the transistor M2_1 may be connected to each other. A source of the transistor M2_1 may be connected to the ground. In addition, a gate of the transistor M1_1 and a gate of the transistor M2_1 may be connected to each other, and the gate of the transistor M1_1 and the gate of the transistor M2_1 may receive the clock signal CLK1 through a switch SW1.

A source of the transistor M3_1 may be connected to one end of the load capacitor C_{LOAD}, and a negative voltage V_{NEG} may be output from the source of the transistor M3_1. A drain of the transistor M3_1 and a drain of the transistor M4_1 may be connected to each other, and a source of the transistor M4_1 may be connected to the ground. In addition, a gate of the transistor M1_1 and a gate of the transistor M2_1 may be connected to each other, and the gate of the transistor M1_1 and the gate of the transistor M2_1 may receive the clock signal CLK1 through a switch SW3. The clock signal CLK1 applied to the gate of the transistor M3_1 and the gate of the transistor M4_1 and the clock signal CLK1 applied to the gate of the transistor M11 and the gate of the transistor M2_1 may be the same clock signal.

The second transistor group 220 may be operated in the second mode and driven (or operated) by a clock signal CLK2. The second transistor group 220 may include a transistor M1_2, a transistor M2_2, a transistor M3_2, and a transistor M4_2. In terms of the pump capacitor C_{PUMP} and the load capacitor C_{LOAD}, a connection relationship of the transistors M1_2 to M4_2 may be similar to that of the transistors M1 to M4 in FIG. 2.

A source of the transistor M1_2 may be connected to a power supply voltage V_{DD}, and a drain of the transistor M1_2 and a drain of the transistor M2_2 may be connected to each other. A source of the transistor M2_2 may be connected to the ground. In addition, a gate of the transistor M1_2 and a gate of the transistor M2_2 may be connected to each other, and the gate of the transistor M1_2 and the gate of the transistor M2_2 may receive the clock signal CLK2 through a switch SW2.

A source of the transistor M32 may be connected to one end of the load capacitor C_{LOAD}, and a negative voltage V_{NEG} may be output from the source of the transistor M3_2. A drain of the transistor M3_2 and a drain of the transistor M4_2 may be connected to each other, and a source of the transistor M4_2 may be connected to the ground. In addition, a gate of the transistor M3_2 and a gate of the transistor M4_2 may be connected to each other, and the gate of the transistor M3_2 and the gate of the transistor M4_2 may receive the clock signal CLK2 through a switch SW4. The clock signal CLK2 applied to the gate of the transistor M3_2 and the gate of the transistor M4_2 and the clock signal CLK2 applied to the gate of the transistor M1_2 and the gate of the transistor M2_2 may be the same clock signal.

In the first mode, the switches SW1 and SW3 may be turned on, and the first transistor group 210 may be operated. That is, when the switches SW1 and SW3 are turned on, the clock signal CLK1 may be input to the first transistor group 210, and the operation of the first transistor group 210 may generate the negative voltage VNEG.

When the clock signal CLK1 is at a low level in the first mode, the transistors M1_1 and M4_1 may be turned on, and the transistors M2_1 and M3_1 may be turned off. Accordingly, the pump capacitor C_{PUMP} may be charged with the power supply voltage V_{DD}. When the clock signal CLK1 is at a high level in the first mode, the transistors M2_1 and M31 may be turned on, and the transistors M1_1 and M4_1 may be turned off. Accordingly, the negative voltage V_{NEG} having −V_{DD} may be output.

In the second mode, the switches SW2 and SW4 may be turned on, and the second transistor group 220 may be operated. That is, when the switches SW2 and SW4 are turned on, the clock signal CLK2 may be input to the second transistor group 220, and the operation of the second transistor group 220 may generate the negative voltage VNEG.

When the clock signal CLK2 is at a low level in the second mode, the transistors M1_2 and M4_2 may be turned on, and the transistors M2_2 and M3_2 may be turned off. Accordingly, the pump capacitor C_{PUMP} may be charged with the power supply voltage V_{DD}. When the clock signal CLK2 is at a high level in the second mode, the transistors M2_2 and M3_2 may be turned on, and the transistors M1_2 and M4_2 may be turned off. Accordingly, the negative voltage V_{NEG} having −V_{DD} may be output.

As described above with reference to FIG. 4, the sizes of the transistors may be set differently from each other when a frequency of the clock signal CLK1 and a frequency of the clock signal CLK2 are set to different values. For example, when the frequency of the clock signal CLK2 is higher than the frequency of the clock signal CLK1, a size of the second transistor group 220 and a size of the first transistor group 210 may have a relationship expressed by Equation 3 below. That is, when the frequency of the clock signal CLK2 is higher than the frequency of the clock signal CLK1, the size of the second transistor group 220 may be set larger than the size of the first transistor group 210.

$${SIZE}_{210} < {SIZE}_{220} \qquad ( Equation 3 )$$

In Equation 3, SIZE₂₁₀ represents the size of the first transistor group 210, and SIZE₂₂₀ represents the size of the second transistor group 220. Here, the size SIZE₂₁₀ of the first transistor group 210 indicates each size of the transistors M1_1 to M4_1 included in the first transistor group 210. In addition, the size SIZE₂₂₀ of the second transistor group 220 indicates each size of the transistors M1_2 to M4_2 included in the second transistor group 220.

The charge pump circuit 200b may stably output the negative voltage V_{NEG} even though the frequency of the clock signal CLK1 and the frequency of the clock signal CLK2 are set differently from each other in the charge pump circuit 200b of FIG. 5.

The following describes an example of the first mode and that of the second mode with reference to FIG. 5. The second mode may indicate a start-up mode of the charge pump circuit 200b, and the first mode may indicate a mode other than the start-up mode of the charge pump circuit 200b. Here, the start-up mode may indicate a period when the charge pump circuit 200b is initially driven, and the mode other than the start-up mode may indicate a period after the period when the charge pump circuit 200b is initially driven. In the start-up mode, the charge pump circuit 200b may need to quickly output the negative voltage V_{NEG}. To this end, the frequency of the clock signal may be set high in the start-up mode. In addition, in a mode other than the start-up mode (e.g., after the start-up mode), the frequency of the clock signal may be set low.

In the start-up mode, the switches SW2 and SW4 may be turned on, and the clock signal CLK2 may operate the second transistor group 220. Here, the frequency of the clock signal CLK2 may be set higher than the frequency of the clock signal CLK1. Accordingly, the negative voltage V_{NEG} may be quickly output by operating the second transistor group 220. On the other hand, in a mode other than the start-up mode, the switches SW1 and SW3 may be turned on, and the first transistor group 210 may be operated. Accordingly, the negative voltage V_{NEG} may be output by operating the first transistor group 210. Here, the negative voltage V_{NEG} may be stably output by setting the size of the second transistor group 220 to be larger than the size of the first transistor group 210.

The following describes another example of the first mode and that of the second mode with reference to FIG. 5. The first mode may be a reception mode, and the second mode may be a transmission mode. Here, the reception mode may indicate a case where a communication module equipped with the charge pump circuit 200b is in the reception mode, and the transmission mode may indicate a case where the communication module equipped with the charge pump circuit 200b is in the transmission mode. A reception signal may be weak in the reception mode, and a spur occurring in the charge pump circuit 200b may thus have a significant influence. Accordingly, the clock signal frequency of the charge pump circuit 200b may be set low in the reception mode. On the other hand, a transmission signal may be strong in the transmission mode, and the spur occurring in the charge pump circuit 200b may thus have an insignificant influence. Accordingly, the clock signal frequency of the charge pump circuit 200b may be set high in the transmission mode.

In the reception mode, the switches SW1 and SW3 may be turned on, and the clock signal CLK1 may operate the first transistor group 210. Here, the frequency of the clock signal CLK1 may be set lower than the frequency of the clock signal CLK2. Accordingly, the negative voltage V_{NEG} may be output by the operation of the first transistor group 210, and the occurrence of the spur may be reduced. On the other hand, in the transmission mode, the switches SW2 and SW4 may be turned on, and the second transistor group 220, may be operated. Accordingly, the negative voltage V_{NEG} may be output by operating the second transistor group 220. Here, the negative voltage V_{NEG} may be stably output by setting the size of the second transistor group 220 to be larger than the size of the first transistor group 210.

FIG. 6 is a circuit diagram showing a charge pump circuit 200c in another one or more embodiments.

As shown in FIG. 6, the charge pump circuit 200c in another embodiment may include a first transistor group 210 operating in a first mode, a second transistor group 220 operating in a second mode, a third transistor group 230 operating in a third mode, a pump capacitor C_{PUMP}, and a load capacitor C_{LOAD}. The charge pump circuit 200c of FIG. 6 is similar to the charge pump circuit 200b of FIG. 5, except for adding the third transistor group 230. Therefore, the description omits redundant descriptions.

The third transistor group 230 may be operated in the third mode and driven (or operated) by a clock signal CLK3. The third transistor group 230 may include a transistor M1_3, a transistor M2_3, a transistor M3_3, and a transistor M4_3. In terms of the pump capacitor C_{PUMP} and the load capacitor C_{LOAD}, a connection relationship of the transistors M1_3 to M4_3 may be similar to that of the transistors M1 to M4 in FIG. 2.

A source of the transistor M1_3 may be connected to a power supply voltage V_{DD}, and a drain of the transistor M1_3 and a drain of the transistor M2_3 may be connected to each other. A source of the transistor M2_3 may be connected to the ground. In addition, a gate of the transistor M1_3 and a gate of the transistor M2_3 may be connected to each other, and the gate of the transistor M1_3 and the gate of the transistor M2_3 may receive the clock signal CLK3 through a switch SW5.

A source of the transistor M3_3 may be connected to one end of the load capacitor C_{LOAD}, and a negative voltage V_{NEG} may be output from the source of the transistor M3_3. A drain of the transistor M3_3 and a drain of the transistor M4_3 may be connected to each other, and a source of the transistor M4_3 may be connected to the ground. In addition, a gate of the transistor M3_3 and a gate of the transistor M4_3 may be connected to each other, and the gate of the transistor M3_3 and the gate of the transistor M4_3 may receive the clock signal CLK3 through a switch SW6. The clock signal CLK3 applied to the gate of the transistor M3_3 and the gate of the transistor M4_3 and the clock signal CLK3 applied to the gate of the transistor M1_3 and the gate of the transistor M2_3 may be the same clock signal.

In the third mode, the switches SW5 and SW6 are turned on, and the third transistor group 230 may be operated (or driven). That is, when the switches SW5 and SW6 are turned on, the clock signal CLK3 may be input to the third transistor group 230, and the operation of the third transistor group 230 may generate the negative voltage VNEG.

When the clock signal CLK3 is at a low level in the third mode, the transistors M1_3 and M4_3 may be turned on, and the transistors M2_3 and M3_3 may be turned off. Accordingly, the pump capacitor C_{PUMP} may be charged with the power supply voltage V_{DD}. When the clock signal CLK3 is at a high level in the third mode, the transistors M2_3 and M3_3 may be turned on, and the transistors M1_3 and M4_3 may be turned off. Accordingly, the negative voltage V_{NEG} having −V_{DD} may be output.

Meanwhile, the frequency of the clock signal CLK1, the frequency of the clock signal CLK 2, and the frequency of the clock signal CLK3 may be set to different values from one another. For example, the frequency of the clock signal CLK2 may be higher than the frequency of the clock signal CLK1, and the frequency of the clock signal CLK3 may be higher than the frequency of the clock signal CLK2. In this frequency relationship, the size of the first transistor group 210, the size of the second transistor group 220, and the size of the third transistor group 230 may have a relationship expressed by Equation 4 below. That is, a size of a transistor group to which a value of a higher clock frequency is applied may be set to be larger.

$${SIZE}_{210} < {SIZE}_{220} < {SIZE}_{230} \qquad ( Equation 4 )$$

In Equation 4 above, SIZE₂₃₀ represents the size of the third transistor group 230. Here, the size SIZE₂₃₀ of the third transistor group 230 indicates each size of the transistors M1_3 to M4_3 included in the third transistor group 230.

The following describes an example of the first, second, and third modes with reference to FIG. 6. The first mode may be the reception mode described above, the second mode may be the transmission mode described above, and the third mode may be the start-up mode described above.

In the reception mode, switches SW1 and SW3 may be turned on, and the clock signal CLK1 may operate the first transistor group 210. Here, the frequency of the clock signal CLK1 may be set lower than the frequency of the clock signal CLK2. Accordingly, the negative voltage V_{NEG} may be output by the operation of the first transistor group 210, and the occurrence of a spur may be reduced.

On the other hand, switches SW2 and SW4 may be turned on in the transmission mode, and the second transistor group 220, may be operated. Accordingly, the negative voltage V_{NEG} may be output by operating the second transistor group 220. Here, the negative voltage V_{NEG} may be stably output by setting the size of the second transistor group 220 to be larger than the size of the first transistor group 210.

In the start-up mode, the switches SW5 and SW6 may be turned on, and the clock signal CLK3 may operate the third transistor group 230. Here, the frequency of the clock signal CLK3 may be set higher than the frequency of the clock signal CLK2. Accordingly, the negative voltage V_{NEG} may be quickly output by operating the third transistor group 230. Here, the negative voltage V_{NEG} may be stably output by setting the size of the third transistor group 230 to be larger than the size of the second transistor group 220.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A charge pump circuit comprising:
a pump capacitor;
a first transistor group configured to charge the pump capacitor based on a first clock signal having a first frequency; and
a second transistor group configured to charge the pump capacitor based on a second clock signal having a second frequency different from the first frequency,
wherein a size of the second transistor group is different from a size of the first transistor group.

2. The circuit of claim 1, wherein
the second frequency is higher than the first frequency, and the size of the second transistor group is larger than the size of the first transistor group.

3. The circuit of claim 1, wherein
the first transistor group is operated in a first mode, and the second transistor group is operated in a second mode.

4. The circuit of claim 3, wherein
the second mode is a start-up mode of the charge pump circuit, and the first mode is different than the start-up mode.

5. The circuit of claim 4, wherein
the second frequency is higher than the first frequency, and the size of the second transistor group is larger than the size of the first transistor group.

6. The circuit of claim 3, wherein
in the first mode, a communication module comprising the charge pump circuit is in a reception mode, and
in the second mode, the communication module is in a transmission mode.

7. The circuit of claim 6, wherein
the second frequency is higher than the first frequency, and the size of the second transistor group is larger than the size of the first transistor group.

8. The circuit of claim 1, further comprising
a third transistor group configured to charge the pump capacitor based on a third clock signal having a third frequency different from the second frequency,
wherein the size of the first transistor group, the size of the second transistor group, and a size of the third transistor group are different from one another.

9. The circuit of claim 8, wherein
the second frequency is higher than the first frequency, and the third frequency is higher than the second frequency, and
the size of the second transistor group is larger than the size of the first transistor group, and the size of the third transistor group is larger than the size of the second transistor group.

10. The circuit of claim 9, wherein
the first transistor group is operated in a first mode, the second transistor group is operated in a second mode, and the third transistor group is operated in a third mode.

11. The circuit of claim 10, wherein
in the first mode, a communication module comprising the charge pump circuit is in a reception mode,
in the second mode, the communication module is in a transmission mode, and
in the third mode, the charge pump circuit is in a start-up mode.

12. A negative voltage generator comprising:
the circuit of claim 1; and
an oscillator configured to generate the first clock and the second clock to drive the first transistor group and the second transistor group, respectively.

13. An operating method of a charge pump circuit, the method comprising:
generating, in a first mode, a negative voltage using a first transistor group based on a first clock signal; and
generating, in a second mode, the negative voltage using a second transistor group based on a second clock signal,
wherein a frequency of the second clock signal is different from a frequency of the first clock signal, and a size of the second transistor group is different from a size of the first transistor group.

14. The method of claim 13, wherein
the frequency of the second clock signal is higher than the frequency of the first clock signal, and the size of the second transistor group is larger than the size of the first transistor group.

15. The method of claim 14, wherein
the second mode is a start-up mode of the charge pump circuit, and the first mode is a different mode than the start-up mode.

16. The method of claim 14, wherein
in the first mode, a communication module comprising the charge pump circuit is in a reception mode, and
in the second mode, the communication module is in a transmission mode.

17. The method of claim 13, further comprising
generating, in a third mode, the negative voltage using a third transistor group based on a third clock signal,
wherein a frequency of the third clock signal is different from the frequency of the second clock signal, and a size of the third transistor group is different from the size of the second transistor group.

18. The method of claim 17, wherein
the second frequency is higher than the first frequency, and the third frequency is higher than the second frequency,
the size of the second transistor group is larger than the size of the first transistor, and the size of the third transistor is larger than the size of the second transistor group, and
in the first mode, a communication module comprising the charge pump circuit is in a reception mode,
in the second mode, the communication module is in a transmission mode, and
in the third mode, the charge pump circuit is in a start-up mode.

19. A negative voltage generator comprising:
a charge pump circuit comprising a pump capacitor and a plurality of transistor groups having different sizes; and
an oscillator configured to generate a plurality of clock signals having different frequencies to drive the plurality of transistor groups, respectively,
wherein each of the plurality of transistor groups is configured to charge the pump capacitor based on a corresponding clock signal of the plurality of clock signals.

20. The negative voltage generator of claim 19,
wherein a second frequency of the different frequencies is higher than a first frequency of the different frequencies,
a size of a second transistor group of the plurality of transistor groups is larger than a size of a first transistor group of the plurality of transistor groups, and
the second transistor group is operated in a start-up mode, and the first transistor group is operated in a different than the start-up mode.
